(19) United States
(12) Patent Application Publication
(10) Pub. No.: US 2007/0262409 A1
(43) Pub. Date: Nov. 15, 2007

(54) Lead frame and semiconductor device using the same

(76) Inventors: Yoichiro Nozaki, Osaka (JP); Yasuhiro Takehana, Shiga (JP); Akira Oga, Shiga (JP); Toshiyuki Fukuda, Kyoto (JP); Seiji Fujiwara, Kyoto (JP)

Correspondence Address: MCDERMOTT WILL & EMERY LLP, 600 13TH STREET, NW, WASHINGTON, DC, 20005-3096, US

(21) Appl. No.: 11/705,509

(22) Filed: Feb. 13, 2007

(30) Foreign Application Priority Data
May 9, 2006 (JP) 2006-130369

(51) Int. Cl. H01L 23/495

(52) U.S. Cl. 257/487; 257/669; 257/E23.045; 257/E23.051

(57) ABSTRACT

A lead frame includes: a die pad for holding a semiconductor chip; a radiator plate extending outward from one side face of the die pad and another side face thereof opposite the one side; a plurality of inner leads arranged opposite respective sides of the die pad other than the sides from which the radiator plate extends so as to interpose the die pad; and a plurality of outer leads formed outside the plurality of inner leads and connected to the inner leads. At least one of the plurality of inner leads serves as a ground lead connected to the die pad. In the radiator plate, an island bonding area of which potential is equal to that of the die pad is formed, a first slit is formed around three sides of the island bonding area, and the other side is connected to the radiator plate through a joint part.

### CROSS REFERENCE TO RELATED APPLICATIONS

This Non-provisional application claims priority under 35 U.S.C. §119(a) on Patent Application No. 2006-130369 filed in Japan on May 9, 2006, the entire contents of which are hereby incorporated by reference.

### BACKGROUND OF THE INVENTION

The present invention relates to a lead frame and a semiconductor device using it, and more particularly relates to a lead frame required to have high heat radiation for releasing heat of a high breakdown voltage element and the like and a semiconductor device using it.

Conventionally, in a lead frame required to have high heat radiation for releasing heat of a high breakdown voltage element and the like, peeling off is caused at an interface between a sealing resin material and the lead frame or at an interface between the sealing resin material and a die pad. Once such peeling off is caused, it develops to cause peeling off between a wire bond or a bonding area and breakage of the wire bond, thereby lowering reliability in electric connection of the electric parts. Accordingly, a lead frame and a semiconductor device using it have been desired which is prevented from lowering of reliability in electric connection of the electric parts, which is caused due to peeling off between the wire bond and the bonding area or breakage of the wire bond, by preventing the peeling off at the interfaces and development thereof.

FIG. 7 shows one example of a conventional lead frame for a semiconductor device which is required to have high heat radiation for releasing heat of a high breakdown voltage element and the like.

As shown in FIG. 7, the conventional lead frame 101 includes: a die pad 102 for holding a semiconductor chip; a radiator plate 104 extending in parallel to tie bars 103 and formed so as to interpose the die pad 102; and a plurality of inner leads 105 extending from the tie bars 103 toward the die pad 102 and spaced apart from the die pad 102, wherein one of the plurality of inner leads 105 is connected to the die pad 102 to serve as a GND (ground) lead 106.

FIG. 8 and FIG. 9 each show one example of a conventional semiconductor device including a high breakdown voltage element and the like which is a semiconductor device using the lead frame 101 shown in FIG. 7.

As shown in FIG. 8, in the conventional semiconductor device including the high breakdown voltage element and the like, a semiconductor chip 107 is die bonded on the die pad 102 of the lead frame 101, and electrode pads 108 and a ground electrode pad 109 of the semiconductor chip 107 are wire bonded to bonding areas 110 of the inner leads 104 and a GND connection bonding area 111, respectively, by means of metal thin lines 112.

In the semiconductor device including the high breakdown voltage element and the like shown in FIG. 9, the ground electrode pad 109 of the semiconductor chip 107 is wire bonded to an on-GND-lead bonding area 113 of the GND lead 106 by means of the metal thin line 112.

The semiconductor chip 107 held by the lead frame 101 and the metal thin lines 112 are sealed by a sealing resin material 114, and a part of the radiator plate 104 which is exposed from the sealing resin material 114 and the outer leads 115 are subjected to resin burr removal, tie-bar cutting, and cut-bending, thereby obtaining the semiconductor device shown in FIG. 8 or FIG. 9. In FIG. 7, a region to be sealed by the sealing resin material 114 is indicated by a broken line as a sealing region 116. A part of the radiator plate 104 which is exposed from the sealing resin material 114 and the outer leads 115 are bent into gull wing forms.

In a semiconductor device disclosed in Japanese Patent Application Laid Open Publication No. 6-21303A, when at least one hole is formed in the vicinity of the wire bonding area of the lead frame, peeling off caused by thermal stress between the surface of an inner lead and the sealing resin material can be prevented, preventing the wire bond from being broken by the pealing off.

Referring to Japanese Patent Application Laid Open Publication No. 2-78262A, the inner leads and the GND lead which are covered with the sealing resin material have parts which are bent in-plan and have a narrow width to prevent outside moisture from entering. This means an increase in humidity resistance, thereby obtaining a highly reliable semiconductor device.

The conventional semiconductor device using the lead frame for holding the high breakdown voltage element and the like, however, involves the following problems.

FIG. 10A is a sectional view taken along the line Xa-Xa of the conventional semiconductor device shown in FIG. 8, and FIG. 10B shows in an enlarged scale a region D indicated in FIG. 10A.

As shown in FIG. 10B, in the semiconductor device using the conventional lead frame 101, which receives external mechanical stress in cut-bending and the like of the radiator plate 104, pealing off 121 is liable to be caused between the sealing resin material 114 and the radiator plate 104 from the edge of the sealing resin material 114 toward the inside. Further, thermal stress is generated due to difference in thermal expansion of the sealing resin material 114, the lead frame 101, and the semiconductor chop 107 in packaging reflow to cause pealing off 122 between the sealing resin material 114 and the lead frame 101 from the die pad 102 that holes the semiconductor chip 107 toward the outside. Accordingly, if the inward peeling off 121 or the outward peeling off 122 reaches the GND connection bonding area 111 in the lead frame 101, the wire bond of the thin metal lines 112 is liable be broken, lowering the reliability in electrical connection.

FIG. 11A shows a structure in section taken along the line XIa-XIa of the conventional semiconductor device shown in FIG. 9, and FIG. 11B shows in an enlarged scale a region F indicated in FIG. 11A.

As shown in FIG. 11B, even in the case where the ground electrode pad 109 of the semiconductor chip 107 is wire bonded to the on-GND-lead bonding area 113 by means of the metal thin line 112, pealing off similar to that shown in FIG. 10B develops to lower the reliability in electric connection.

As explained in the conventional example disclosed in Japanese Patent Application Laid Open Publication No. 6-21303A, when at least one hole is formed in the vicinity of the wire bonding area of the lead frame, pealing off caused by thermal stress between the surface of an inner lead and the sealing resin material can be prevented, preventing breakage of the wire bond by the peeling off. It is impossible, however, to suppress development of peeling off to the bonding area which is caused by mechanical stress at the interface between the sealing resin material and the radiator plate from the edge of the sealing resin material toward the inside or which is caused by thermal stress from the die pad that holds the semiconductor chip toward the outside.

Further, the conventional example disclosed in Japanese Patent Application Laid Open Publication No. 2-78262A, in which parts of the inner leads and the GND lead which are covered with the sealing resin material have parts bent in-plane and having a narrow width, enables to prevent outside humidity from entering, increasing the humidity resistance to obtain a highly reliable semiconductor device. While, development of outward peeling off cased by thermal stress from the die pad that holds the semiconductor chip toward the bonding area cannot be suppressed.

As described above, in the conventional semiconductor devices including the lead frame that holds the semiconductor chip and is required to have high heat radiation, there remains an unsolved problem that it is impossible to suppress either the peeling off 121 between the sealing resin material 114 and the radiator plate 104, which is caused by external mechanical stress and develops from the edge of the sealing resin material 114 toward the inside, and the peeling of 122 between the sealing resin material 114 and the lead frame 101, which is caused by thermal stress generated due to difference in thermal expansion coefficient of the respective component members and develops from the die pad 102 toward the outside.

### SUMMARY OF THE INVENTION

The present invention has been made in view of the foregoing and has its object of attaining a lead frame and a semiconductor device using the lead frame of which reliability in electric connection of the connection parts is not lowered by peeling off, even if it is caused, between a lead frame and a sealing resin material.

To achieve the above object, a lead frame of the present invention includes an island bonding area which is connected to a die pad and has a potential equal to the die pad.

Another lead frame of the present invention has a structure in which trenches are formed in inner leads including a ground lead in a direction perpendicular to the direction that the inner leads extend and the ground lead includes a bent portion bent in the in-plane direction thereof.

Specifically, a first lead frame according to the present invention includes: a die pad for holding a semiconductor chip; a radiator plate extending outward from one side face of the die pad and another side face thereof opposite the one side; a plurality of inner leads arranged opposite respective sides of the die pad other than the sides from which the radiator plate extends so as to interpose the die pad; and a plurality of outer leads formed outside the plurality of inner leads and connected to the inner leads, wherein at least one of the plurality of inner leads serves as a ground lead connected to the die pad, and in the radiator plate, an island bonding area of which potential is equal to that of the die pad is formed, a first slit is formed around three sides of the island bonding area, and the other side is connected to the radiator plate through a joint part.

In the first lead frame, the island bonding area having a potential equal to the die pad is formed in the radiator plate so a to be surrounded at three peripheral sides thereof by the first slit and be connected at the other peripheral side thereof to the radiator plate through the joint part. Accordingly, even if pealing off is caused by mechanical stress at the interface between the sealing resin material and the radiator plate from the edge of the sealing resin material toward the inside or by thermal stress at the interface between the lead frame and the sealing resin material from the die pad that holds the semiconductor chip toward the outside, development of such peeling off to the island bonding area is suppressed. As a result, peeling off at the interface between the wire bond and the bonding area and breakage of the wire bond can be prevented.

In the first lead frame, the island bonding area is preferably formed at a central part in a widthwise direction of the radiator plate which is a direction perpendicular to a direction that the radiator plate extends.

In the first lead frame, preferably, a trench extending in a direction perpendicular to a direction that the inner leads extend is formed in a surface portion of each of the inner leads including the ground lead, and the ground lead includes at least two bent portions bent in an in-plane direction of the ground lead.

The above arrangements increase the creepage distance of the ground lead between the die pad and the outer lead to prevent pealing off caused by mechanical stress at the interface between the sealing resin material and the radiator plate from the edge of the sealing material resin toward the inside further reliably.

In the first lead frame, the island bonding area is preferably in a quadrangular shape, a circular shape, an elliptical shape, a U-shape, or a V-shape in plan.

In the first lead frame, preferably, the joint part has a width smaller than the island bonding area.

With either of the above arrangements, adhesiveness of the sealing resin material to the island bonding area increases.

In the first lead frame, the first slit preferably includes notches extending toward the inner leads on the respective sides of a part of the joint part which is connected to the radiator plate.

With the above arrangement, adhesiveness of the sealing resin material to the island bonding area increases.

In the first lead frame, the joint part is formed preferably on an opposite side of the island boding area from the die pad.

In the first lead frame, preferably, a trench extending in a direction perpendicular to a direction that the joint part extends is formed in a surface portion of the joint part.

Either of the above arrangements increases the creepage distance of the joint part, suppressing development of peeling off further.

In the first lead frame, it is preferable to form a second slit in a region of the radiator plate on an opposite side of the island bonding area from the die pad, the region being sealed by a sealing resin material.

In the first lead frame, the joint part is preferably formed on a die pad side of the island bonding area.

In this case, it is preferable to form a third slit between the die pad and the first slit of the radiator plate.

In the first lead frame, it is preferable to form a fourth slit in a region of the radiator plate on an opposite side of the die pad from the island bonding area.

A second lead frame according to the present invention includes: a die pad for holding a semiconductor chip; a radiator plate extending outward from one side face of the die pad and another side face thereof opposite the one side; a plurality of inner leads arranged opposite respective sides of the die pad other than the sides from which the radiator plate extends so as to interpose the die pad; and a plurality of outer leads formed outside the plurality of inner leads and connected to the inner leads, wherein at least one of the plurality of inner leads serves as a ground lead connected to the die pad, a trench extending in a direction perpendicular to a direction that the inner leads extend is formed in a surface portion of each of the inner leads including the ground lead, and the ground lead includes at least two bent portions bent in an in-plane direction of the ground lead.

In the second lead frame, the trench extending in the direction perpendicular to the direction that the inner leads extend is formed in the surface portion of each inner lead including the ground lead, and the ground lead includes at least two bent portions bent in the in-plane direction of the ground lead. Accordingly, the creepage distance of the ground lead from the die pad to the outer lead increases, and adhesiveness of the sealing resin material to the lead frame increases, preventing peeling off caused by mechanical stress or by thermal stress between the sealing resin material and the lead frame.

In the first or second lead frame, preferably, a part of the ground lead which is connected to the die pad has a width smaller than the other inner leads.

In the first or second lead frame, preferably, at least one out of the plurality of outer leads which is adjacent to an outer lead connected to the ground lead is not connected to any of the inner leads.

A semiconductor device according to the present invention is directed to a semiconductor device using the first or second lead frame of the present invention and includes: a semiconductor chip held on the die pad and having electrode pads and a ground electrode pad; and a sealing part made of a sealing resin material for sealing the die pad including the semiconductor chip, each of the inner leads, and a part of the radiator plate which includes the island bonding area, wherein in the semiconductor chip, the electrode pads are connected to the inner leads electrically by means of a metal thin line, and the ground electrode pad is connected to the island bonding area or a bonding area of the ground lead electrically by means of a metal thin line, the island bonding area is covered at peripheral sides thereof, except a side connected to the joint part, with the sealing resin material, and the other part of the radiator plate and each of the outer leads are bent in gull wind forms.

In the semiconductor device according to the present invention, preferably, the semiconductor chip is a high breakdown voltage element.

According to the lead frames and the semiconductor devices using any of the lead frames of the present invention, even if peeling off is caused between the lead frame and the sealing resin material, development of the peeling off is suppressed, maintaining reliability in electric connection of the electric parts thereof.

### BRIEF DESCRIPTION OF THE DRAWINGS

FIG. 1 is a plan view showing a structure of a lead frame according to Embodiment 1 of the present invention.

FIG. 2 is a plan view showing a structure of a lead frame according to Embodiment 2 of the present invention.

FIG. 3 is a plan view showing a structure of a lead frame according to Embodiment 3 of the present invention.

FIG. 4 is a plan view showing a structure of a semiconductor device according to Embodiment 4 of the present invention.

FIG. 5 is a plan view showing a semiconductor device according to one modified example of Embodiment 4 of the present invention.

FIG. 6A is a sectional view taken along the line VIa-VIa in FIG.4, and FIG. 6B is a sectional view taken along the line VIb-VIb in FIG. 5.

FIG. 7 is a plan view showing a conventional lead frame for a semiconductor device including a high breakdown voltage element and the like.

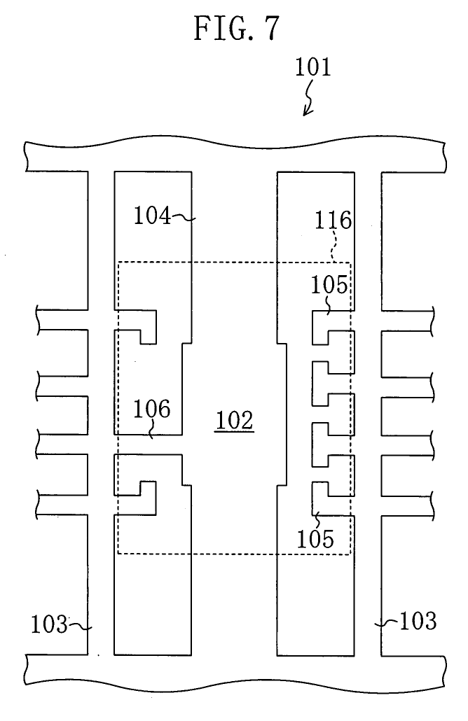

FIG. 8 is a plan view showing one example of a semiconductor device including a high breakdown voltage element and the like using the conventional lead frame shown in FIG. 7.

FIG. 9 is a plan view showing another example of a semiconductor device including a high breakdown voltage element and the like using the conventional lead frame shown in FIG. 7.

FIG. 10A is a sectional view taken along the line Xa-Xa in FIG. 8, and FIG. 10B is a sectional view in an enlarged scale of a region D in FIG. 10A.

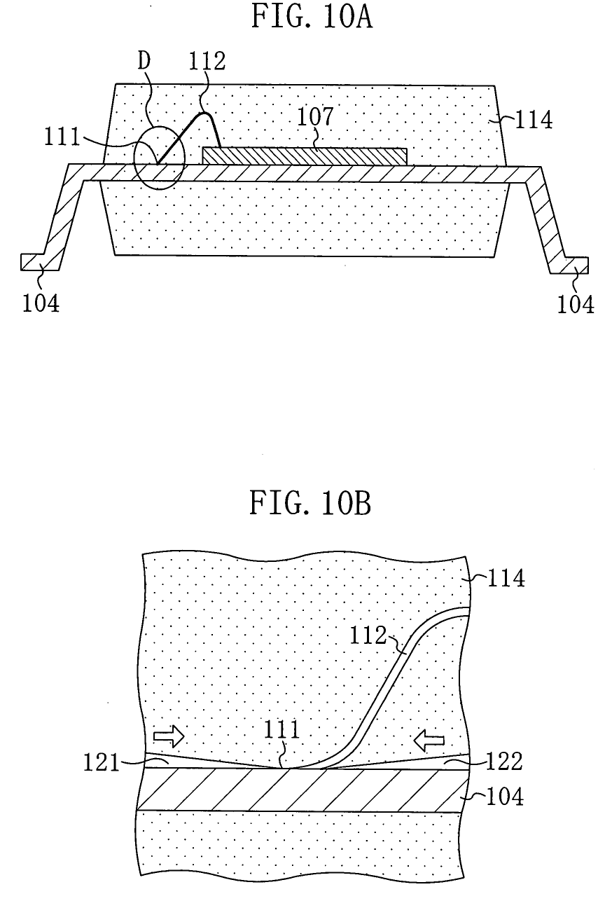

FIG. 11A is a sectional view taken along the line XIa-XIa in FIG. 9, and FIG. 11B is a sectional view in an enlarged scale of a region F in FIG. 11A.

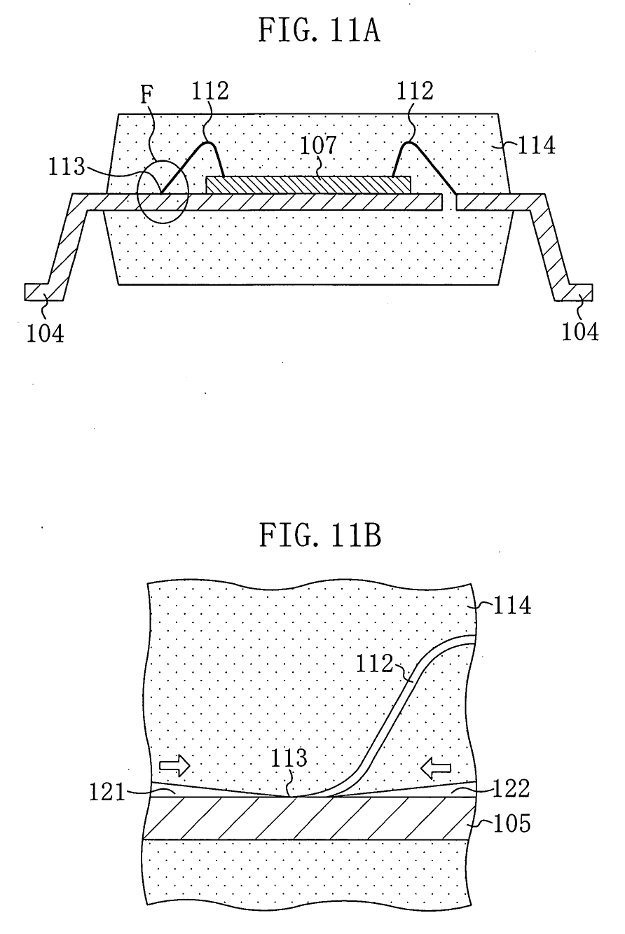

### DESCRIPTION OF THE PREFERRED EMBODIMENTS

### Embodiment 1

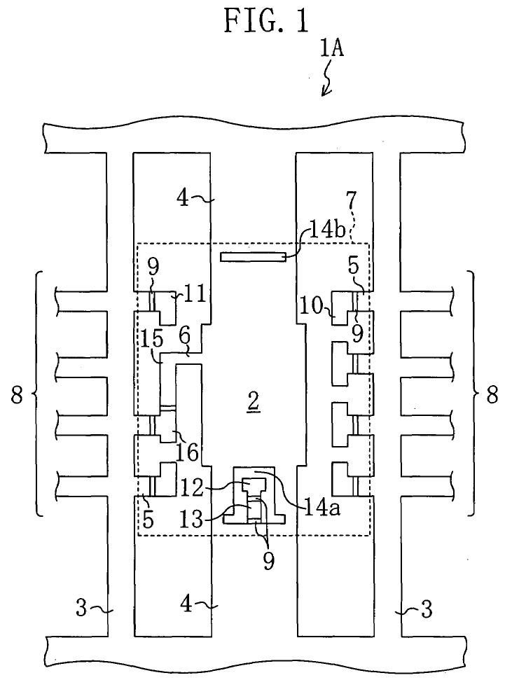

Embodiment 1 of the present invention will be described below with reference to FIG. 1.

FIG. 1 shows one example in plan of a lead frame used for holding a high breakdown voltage element according to Embodiment 1 of the present invention. The lead frame according to the present embodiment is formed of a thin film made of a metal excellent in thermal conductivity, such as a copper alloy, and having a thickness of approximately 0.25 mm.

As shown in FIG. 1, the lead frame 1A having a width of, for example, 2.2 mm includes: a die pad 2 for fixing and holding a semiconductor chip; radiator plates 4 which are formed in parallel with tie bars 3 arranged on the respective sides of the radiator plates 4 so as to interpose the die pad 2 and which have a width of, for example, 1.5 mm and; and a plurality of inner leads extending from the tie bars 3 toward the die pad 2, wherein one of the plurality of inner leads 5 serves as a GND (ground) lead 6 connected to the die pad 2. The number of inner leads 5 is set to seven, and one of them serves as the GND lead 6 herein, but the number thereof is not limited to seven only if it is equal to the number of necessary elements. Further, FIG. 1 indicates a sealing region 7 where a semiconductor device using the lead frame 1A is to be sealed by a sealing resin material.

The inner leads 5 are connected to outer leads 8 through the tie bars 3. At least one trench 9 is formed in a part of each inner lead 5 on the outer lead 8 side while a protrusion 10 is formed at the end of each inner lead 5 on the die pad 2 side.

The trenches 9 are formed in the surface portions of the inner leads 5 in a direction perpendicular to the direction that the inner leads 5 extend by half-etching or the like, and have a depth of, for example, 0.09 mm. Formation of the trench 9 in each inner lead 5 suppresses peeling off of the sealing resin material from the lead frame 1A, which is caused by mechanical stress or thermal stress generated in cut-bending of the outer leads 8, and suppresses development of the pealing off toward bonding areas 11 of the inner leads 5.

The protrusions 10 of the inner leads 5 protrude, for example, 0.2 mm in the in-plane direction perpendicular to the direction that the inner leads 5 extend. Provision of the protrusion 10 of each inner lead 5 increases the contact area between the inner leads 5 and the sealing resin material, increasing adhesiveness of the sealing resin material to the lead frame 1A to enable suppression of pealing off caused by thermal stress.

In the present embodiment, the depth of the trenches 9 is set to 0.09 mm because an effect of suppressing development of peeling off can be obtained sufficiently with a step difference of approximately 0.09 mm, and therefore, the present invention is not limited to this numerical value. Further, the trenches 9 may be formed by pressing rather than half-etching. The protruding length of the protrusions 10 is not limited to 0.2 mm and may be any arbitrary length only if they are out of contact with the respective adjacent inner leads 5.

The first feature of the lead frame 1A according to the present embodiment lies in that an island bonding area 12 of which potential is equal to that of the die pad 2 is formed in a region of one of the radiation plates 4 which is sealed by the sealing resin material. The island bonding area 12 is located at the central part in the width direction of the corresponding radiator plate 4, in detail, at the central part between the respective sides of the radiator plate 4 which face the inner lead leads 5. The island bonding area 12 is in a rectangular shape having a size of approximately 0.3 mm by 0.2 mm in plan in the present embodiment, but may be in any shape of quadrangles including squares, circles, and ellipses, or in a U-shape, a V-shape, or the like only if it has an area wide enough to be wire bonded. Further, the island bonding area 12 may be formed not only at one point, and a second island bonding area 12 may be formed so as to interpose the die pad 2 As shown in FIG. 1, the island bonding area 12 is connected to the corresponding radiator plate 4 by means of a joint part 13 having a width of 0.15 mm and a length of 0.6 mm in a region opposite the die pad 2 in the radiator plate 4, namely, at a part of the radiator plate 4 apart from the die pad 2. A slit 14a having a width of 0.20 mm is formed by, for example, pressing so as to separate the peripheral sides of the island bonding area 12, except the side connected to the joint part 13, from the radiator plate 4.

In both side portions of the joint part 13 which are connected to the radiator plate 4 and the island bonding area 12, trenches 9 are formed so as to extend toward the inner leads 5. Herein, the width of the joint part 13 is set to 0.15 mm, which is smaller than the width of the island bonding area 12, 0.3 mm, so that the island bonding area 12 is covered from the four sides thereof with the sealing resin material when a semiconductor chip is sealed to the die pad 2 by the sealing resin material. This increases adhesiveness of the sealing resin material to the island bonding area 12, enabling suppression of development of peeling off toward the island bonding area 12.

In the present embodiment, the width of the slit 14a is set to 0.20 mm because development of peeling off between the sealing resin material and the lead frame 1A is suppressed sufficiently with the width of such an extent. Accordingly, the width of the slit 14a is not necessarily set to 0.20 mm. As well, the slit 14a may be formed by etching rather than pressing.

In the present embodiment, the joint part 13 is connected to the corresponding radiator plate 4 at a part thereof on an opposite side of the island bonding area 12 from the die pad 2. This can set the creepage distance from the die pad 2 to the island bonding area 12 longer than that in the case where the island bonding area 12 is connected at a part nearer the die pad 2, suppressing development of peeling off, which is caused by thermal stress between the lead frame 1A and the sealing resin material from the die pad 2 toward the outside, toward the island bonding area 12.

Further, the longer the length of the joint part 13 is set, the more development of the peeling off is suppressed. In the present embodiment, the length of the joint part 13 is set to 0.6 mm, which enables sufficient suppression of development of the peeling off. It is known by experiments that with the joint part 13 having a length of, for example, 0.3 mm, pealing off reaches the island bonding area 12.

Further, notches extending toward the inner leads 5 arranged on the respective sides of the radiator prates 4 are formed at respective sides of the slit 14a where the joint part 13 is connected to the corresponding radiator plate 4. This further extends the creepage distance from the die pad 2 to the island bonding area 12, further suppressing development of peeling off. Moreover, formation of the notches increases adhesiveness of the sealing resin material to the lead frame 1A, suppressing development of peeling off between the lead frame 1A and the sealing resin material from the edge of the sealing resin material toward the inside, which is caused by mechanical stress in cut-bending of the radiator plates 4, and suppressing lowering of humidity resistance accompanied by the development thereof. Hence, the semiconductor device can be prevented from lowering of breakdown voltage, which is caused due to moisture permeation from the edge of the sealing resin material toward the die pad 2 that holds the semiconductor chip. The lowering of humidity resistance can be suppressed sufficiently with the notches of the slit 14A extending approximately 0.1 mm to 0.2 mm toward the inner leads 5 on the respective sides of the radiator plates 4.

The two trenches 9 having a depth of 0.09 mm are formed in the joint part 13 by half etching. This increases the creepage distance from the edge of the sealing resin material to the island bonding area 12. Accordingly, even if peeling off is caused by mechanical stress between the lead frame 1A and the sealing resin material from the edge of the sealing resin material toward the inside, development of the peeling off can be suppressed by the trenches 9. It is noted that the trenches 9 of the joint part 13 is formed by half etching but may be formed by pressing. Further, the number of the trenches 9 may be set appropriately according to the length of the joint part 13.

As described above, in the present invention, formation of the slit 14a results in the island bonding area 12 covered from four sides thereof with the sealing resin material. Accordingly, even if peeling off is caused by mechanical stress between the sealing resin material and one of the radiator plates 4 from the edge of the sealing resin material toward the inside or peeling of is cause by thermal stress between the lead frame 1A and the sealing resin material from the die pad 2 toward the outside, development of such peeling off toward the island bonding area 12 is suppressed. As a result, peeling off between the wire bond and the bonding area and breakage of the wire bond can be prevented. Hence, reliability in electric connection of the connection parts is prevented from being lowered. Further, provision of the island bonding area 12 in one of the radiator plates 4 increases the number of bonding areas capable of being connected electrically to a semiconductor chip held by the die pad 2, which increases the degree of freedom of layout of the semiconductor chip to be held by the die bad 2.

In Embodiment 1, only a slit 14b is formed in the sealing region 7 of the other radiator plate 4 in which the island bonding area 12 is not formed. Formation of the slit 14b, as well as the formation of the slit 14a surrounding the island bonding area 12, increases adhesiveness of the sealing resin material to the lead frame 1A, suppressing development of peeling off between the lead frame 1A and the sealing resin material from the edge of the sealing resin material toward the inside, which is caused by mechanical stress in cut-bending of the radiator plates 4, and suppressing lowering of humidity resistance accompanied by the development thereof. Hence, lowering of breakdown voltage of the semiconductor device, which is caused due to moisture permeation from the edge of the sealing resin material toward the die pad 2 that holds the semiconductor chip, is prevented. When the width of the slit 14b is set to approximately ⅔ or larger of the width of the radiator plate 4, the lowering of humidity resistance can be suppressed sufficiently.

Referring to the second feature of the lead frame 1A according to Embodiment 1, the GND lead 6 includes two bent portions 15 bent in its plane. This extends the creepage distance from the die pad 2 to the corresponding tie bar 3 when compared with the case where the GND lead 6 with no bent portions 15 is connected to the die pad 2. In the present embodiment, extension of the creepage distance from the die pad 2 to an on-GND-lead bonding area 16 increases adhesiveness of the sealing resin material to the GND lead 6, thereby suppressing development of peeling off caused by thermal stress from the die pad 2 toward the outside. It is noted that the number of bent portions 15 formed in the GND lead 6 is not limited to two.

Moreover, as shown in FIG. 1, the trenches 9 for further extending the creepage distance from the die pad 2 to the corresponding tie bar 3 is formed in the GND lead 6 in a direction perpendicular to the direction that the GND lead 6 extends. Further, the width of a part of the GND 6 which is connected to the die pad 2 is set ½ smaller than the width of the other inner leads 5. To set the width of the connection part of the GND lead 6 to be smaller than the width of the other inner leads 5 increases adhesiveness of the sealing resin material to the connection part, suppressing development of peeling off, which is caused from the die pad 2 toward the outside, toward the on-GND-lead bonding area 16. It is noted that though the two trenches 9 are formed in the GND lead 6 and the width at the connection part thereof is set approximately ½ of the width of the inner leads 5, the present invention is not limited thereto.

Comparatively large potential difference is caused between the outer lead 8 arranged on the outward extension of the GND lead 6 and an outer lead 8 arranged on the outward extension of an inner lead 5 adjacent to the GND lead 6, and therefore, it is necessary to set the distance for insulation between the outer lead 8 connected to the GND lead 6 and the other outer lead 8 adjacent thereto to be large for allowing the lead frame 1A to hold a semiconductor chip including a high breakdown voltage element. Accordingly, in the present embodiment, one of the other outer leads 8 adjacent to the outer lead 8 connected to the GND lead 6 is not connected to any inner leads 5 and is removed after a resin sealing step to present a state in which the pin is lacked.

Accordingly, in Embodiment 1, the GND lead 6, which includes a plurality of bent portions 15 for extending the creepage distance, is connected to the die pad 2 on the extension of the outer lead 8 that is not connected to any inner leads 5 in a space of the adjacent inner lead 5 in the state in which the pin is lacked. In this way, formation of a plurality of bent portions in the GND lead 6 for extending the creepage distance from the die pad 2 needs no additional area, enabling size reduction of a semiconductor device including a high breakdown voltage element. It is noted that the number of bent portions formed in the GND lead 6 is not limited to two. As well, the GND lead 6 may be connected to the die pad 2 on an extension of any one of the outer leads 8 other than the outer lead 8 that is connected to any inner leads 5.

### Embodiment 2

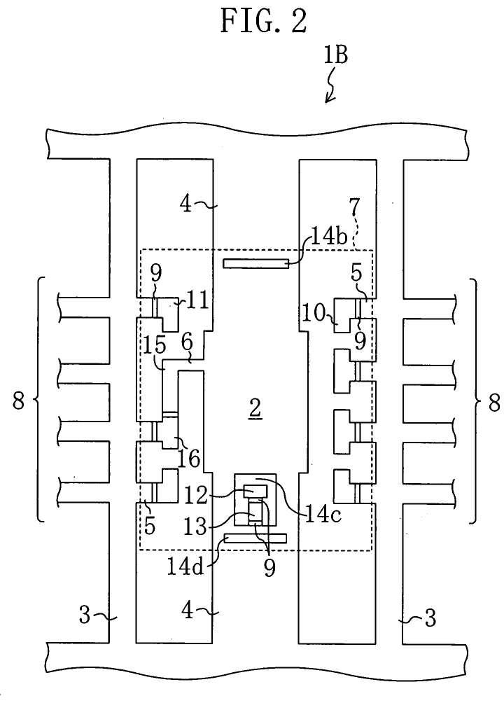

Embodiment 2 of the present invention will be describe below with reference to FIG. 2.

FIG. 2 shows one example in plan of a lead frame used for holding a high breakdown voltage element according to Embodiment 2 of the present invention. In FIG. 2, the same reference numerals are assigned to the same constitutional members as in FIG. 1 for omitting description thereof. In Embodiment 2, only the difference from Embodiment 1 is described.

As shown in FIG. 2, in a lead frame 1B according to Embodiment 2, a slit 14c is formed around the island boding area 12 of the corresponding radiator plate 4, and an independent slit 14d extending in the widthwise direction of the radiator plates 4 is formed in the opposite side of the island bonding area 12 from the die pad 2 separately from the slit 14c, rather than formation of the notches extending in the widthwise direction of the radiator plates 4 in the slit 14c.

Formation of the independent slit 14d in addition to the slit 14c formed around the island bonding area 12 increases adhesiveness of the sealing resin material to the lead frame1B, suppressing development of peeling off caused by mechanical stress in cut-bending of the radiator plates 4 between the lead frame 1B and the sealing resin material from the edge of the sealing resin material toward the inside, and suppressing lowering of humidity resistance accompanied by the development thereof.

Further, the semiconductor device is prevented from lowering of breakdown voltage, which is caused due to moisture permeation from the edge of the sealing resin material toward the die pad 2 that holds the semiconductor chip.

In Embodiment 2, the length of the slit 14d is set to 1 mm relative to the width of the die pad 2, 1.5 mm. Though development of peeling off can be suppressed sufficiently with the slit 14d having a length of such an extent, the length is not limited thereto.

Formation of the slit 14d between the island bonding area 12 and the end of the sealing resin material in Embodiment 2 extends the creepage distance from the end of the sealing resin material to the island bonding area 12 and increases adhesiveness of the sealing resin material to the lead frame 1B to suppress development of peeling off, thereby preventing lowering of reliability in electric connection of the connection parts.

### Embodiment 3

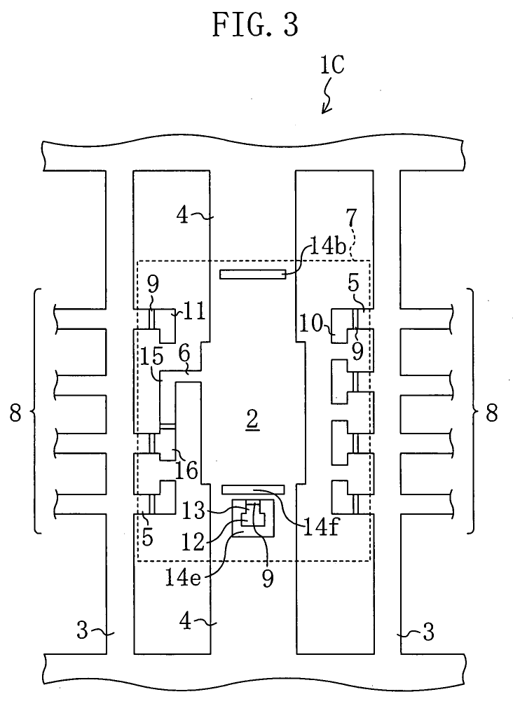

Embodiment 3 of the present invention will be described below with reference to FIG. 3.

FIG. 3 shows one example in plan of a lead frame used for holding a high breakdown voltage element according to Embodiment 3 of the present invention. In FIG. 3, the same reference numerals are assigned to the same constitutional members as in FIG. 1 for omitting description thereof. In Embodiment 3, as well, only the difference from Embodiment 1 is described.

As shown in FIG. 3, in a lead frame 1C according to Embodiment 3, the joint part 13 for connecting the island bonding area 2 and the corresponding radiator plate 4 is arranged on the die pad 2 side. Further, a slit 4e is formed around the island bonding area 12 of the corresponding radiator plate 4, and an independent slit 14f extending in the widthwise direction of the radiator plates 4 is formed between the die pad 2 and the island bonding area 12, rather than formation of the notches extending in the widthwise direction of the radiator plates 4 in the slit 14e.

Provision of the joint part 13 for connecting the island bonding area 12 near the die pad 2 in this way extends the creepage distance from a part of the corresponding radiator plate 4 which corresponds to the edge of the sealing resin material to the island bonding area 12. Accordingly, peeling off caused by mechanical stress in cut-bending of the radiator plates 4 between the lead frame 1C and the sealing resin material from the edge of the sealing resin material toward the inside hardly reaches the island bonding area 12.

While, because provision of the joint part 13 near the die pad 2 shortens the creepage distance from the die pad 2 to the island bonding area 12, peeling off caused by thermal stress between the lead frame 1C and the sealing resin material from the die pad 2 toward the outside may develop to the island bonding area 12. For tackling this problem, in Embodiment 3, the slit 14f having the same structure as the slit 14d in Embodiment 2 is formed between the island bonding area 12 and the die pad 2 for extending the creepage distance from the die pad 2 to the island bonding area 12, thereby suppressing the development of the peeling off caused by thermal stress.

### Embodiment 4

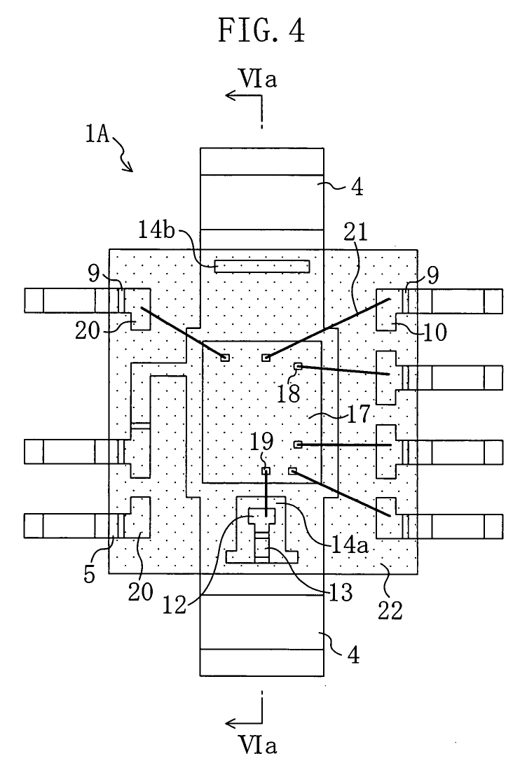

Embodiment 4 of the present invention will be described below with reference to FIG. 4 to FIG. 6.

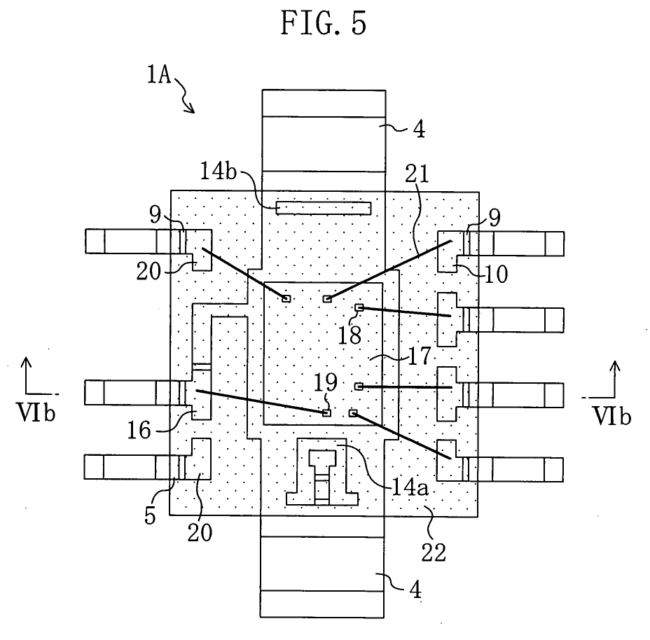

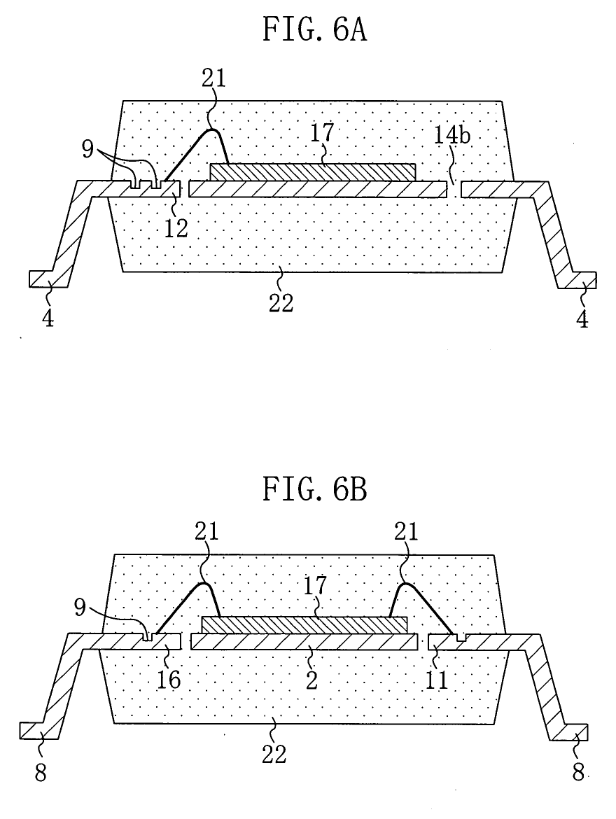

FIG. 4 and FIG. 5 show examples in plan of semiconductor devices according to Embodiment 4 of the present invention each of which allows a lead frame to hold a high breakdown voltage element. FIG. 6A is a sectional view taken along the line VIa-VIa in FIG. 4, and FIG. 6B is a sectional view taken along the line VIb-VIb in FIG. 5. Embodiment 4 refers to examples of semiconductor devices using the lead frame 1A according to Embodiment 1. Therefore, in FIG. 4 to FIG. 6, the same reference numerals are assigned to the same constitutional members as in FIG. 1 for omitting description thereof.

As shown in FIG. 4, in the semiconductor device according to the example of Embodiment 4, a semiconductor chip 17 including a high breakdown voltage element with electrode pads 18 and a ground electrode pad 19 is die bonded on the die pad 2 of the lead frame 1A by a conductive adhesive. It is noted that though the conductive adhesive is used for die boding the semiconductor chip 17 in the present embodiment, a soldering material or the like may be used rather than the conductive adhesive. Further, the semiconductor chip 17 is not limited to the high breakdown voltage element only if the semiconductor chip 17 requires the semiconductor device to have high heat radiation.

The electrode pads 18 and the ground electrode pad 19 of the semiconductor chip 17 die bonded on the die pad 2 are wire bonded and connected electrically to bonding areas 20 of the inner leads 5 and the island bonding area 12, respectively, by means of the metal thin lines 21. In the present embodiment, the ground electrode pad 19 of the semiconductor chip 17 is wire bonded to the island bonding area 12, but the ground electrode pad 19 may be wire bonded to the on-GND-lead bonding area 16 by means of the metal thin lines 21, as shown in the modified example in FIG. 5.

The sealing region 7 of the lead frame 1A which is connected electrically to the semiconductor chip 17 is sealed by a sealing part 22 made of a sealing resin material, such as epoxy resin or the like by transfer molding. In a resin sealing step, the sealing resin material is filled in the trenches 9 and the slit 14a. In this step, parts of the radiator plates 4, the tie bars 3, and the outer leads 8 connected to the inner leads 5, which are exposed from the sealing part 22, are subjected to resin burr removal. Further, the tie bars 3 are tie-bar cut. An outer lead 8 not connected to an inner lead 5 adjacent to the GND lead 6 is cut out, thereby presenting the state in which the pin is lacked. The parts of the radiator plates 4 and the outer leads 8 are lead-cut and bent to be in gull wing forms.

The thus structured semiconductor device according to Embodiment 4 includes the island bonding area 12 electrically connected to the ground electrode pad 19 of the semiconductor chip 17 by means of the metal thin line 21 in the sealing part 22 on the lead frame 1A. Wherein, the peripheral sides of the island bonding area 12 except the side connected to the joint part 13 is separated from the lead frame 1A by the slit 14a.

Comparison is made below between the semiconductor device using the lead frame 1A for a high breakdown voltage element according to Embodiment 4 and a semiconductor device using a conventional lead frame for a high breakdown voltage element.

Table 1 indicates ratios of occurrence of defects that peeling off from the edge of the sealing part 22 toward the inside reaches the GND connection bonding area (the island bonding area 12 in the present invention) in THB (temperature humidity bias) tests under the conditions of 85° C. temperature value, 85% relative humidity, and 1000-hour source voltage application and ratios of occurrence of defects that peeling off from the die pad that holds the semiconductor chip toward the outside reaches the GND connection bonding area in thermal shock tests of 100 cycle repetition of temperature cycling between −65° C. and 150° C.

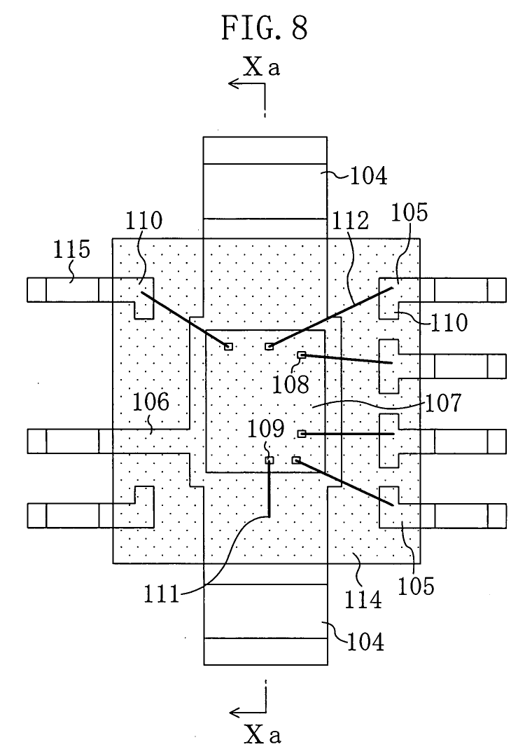

TABLE 1

| | Tests | |
|---|---|---|
| | | Thermal |
| | | shock test |
| | THB test | 100 cycles |
| | 85° C., | between |
| | 85% RH, | −65° C. |
| | 1000 hours | and 150° C., |
| Peeling off reaching island bonding area in | 0/20 | 0/20 |
| high breakdown voltage semiconductor | | |
| device of present invention shown in FIG. 4 | | |
| Peeling off reaching GND connection | 7/18 NG | 12/20 NG |
| bonding area in conventional high | | |
| breakdown voltage semiconductor device | | |
| shown in FIG. 8 | | |

As can be understood from Table 1, no defect occurs in the semiconductor according to Embodiment 4 shown in FIG. 4 in both the tests. In contrast, in the semiconductor device using the conventional lead frame shown in FIG. 8, the defects occur in seven THB tests out of 18, and the defects occur in 12 thermal shock tests out of 20.

Table 2 indicates ratios of occurrence of defects that breakdown voltage lowers due to lowering of humidity resistance accompanied by peeling off development in THB tests under the conditions of 85° C. temperature value, 85% relative humidity, and 1000-hour source voltage application.

TABLE 2

| | Test |
|---|---|
| | THB test |
| | 85° C., |
| | 85% RH, |
| | 1000 hours |
| Breakdown voltage lowering of high breakdown voltage | 0/15 |
| semiconductor device according to the present invention | |
| shown in FIG. 4 | |
| Breakdown voltage lowering of conventional high voltage | 3/15 NG |
| semiconductor device shown in FIG. 8 | |

As can be understood from Table 2, the breakdown voltage does not lower in the semiconductor device according to Embodiment 4 shown in FIG. 4. On the other hand, the breakdown voltage lowers in three tests out of 15 in the semiconductor device using the conventional lead frame shown in FIG. 8.

Further, Table 3 indicates the results of tests equivalent to those in Table 1 performed on a semiconductor device in which the ground electrode pad and the on-GND-lead bonding area 6 are wire bonded.

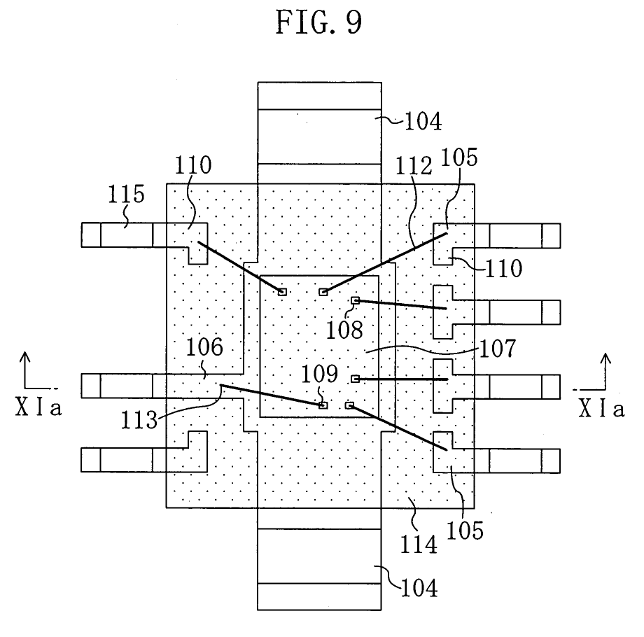

TABLE 3

| | Tests | |
|---|---|---|
| | | Thermal |
| | | shock test |
| | THB test | 100 cycles |
| | 85° C., | between |
| | 85% RH, | −65° C. |
| | 1000 hours | and 150° C., |
| Peeling off reaching on-GND-lead bonding | 0/8 | 0/9 |
| area in high breakdown voltage | | |
| semiconductor device of present invention | | |
| shown in FIG. 5 | | |
| Peeling off reaching on-GND-lead bonding | 6/8 NG | 3/9 NG |
| area in conventional high breakdown voltage | | |
| semiconductor device shown in FIG. 9 | | |

As can be understood from Table 3, in both the tests, no defect occurs in the semiconductor device according to the modified example of Embodiment 4 shown in FIG. 5. On the other hand, defects occur in six THB tests out of eight and defects occur in three thermal shock tests out of nine in the semiconductor device using the conventional lead frame shown in FIG. 9.

As described above, in the semiconductor devices according to Embodiment 4 and the modified example thereof, the island bonding area 12 of which three sides are surrounded by the slit 14a is covered with the sealing resin material. Accordingly, even if peeling off is caused which would develop from the edge of the sealing part 22 toward the inside or from the die pad 2 toward the outside, peeling off development to the island bonding area 12 can be suppressed. Hence, peeling off of the wire bond from the bonding area and breakage of the wire bond can be prevented, preventing lowering of reliability in electric connection of the connection parts.

In the semiconductor device according the modified example, in which the ground electrode pad 19 of the semiconductor chip 17 and the on-GND-lead bonding area 16 are wire bonded, provision of the bent portions 15 in the GND lead 6 extends the creepage distance from the die pad 2 to the on-GND-lead bonding area 16 and further to the corresponding outer lead 8. In addition, formation of at least one trench 9 in the GND lead 6 further extends the creepage distance from the die pad 2 to the corresponding tie bar 3, increasing adhesiveness of the sealing resin material to the GND lead 6. As a result, peeling off caused by thermal stress from the die pad 2 toward the outside is prevented from developing toward the on-GND-lead bonding area 16.

Hence, peeling off at the interface between the wire bond and the bonding area and breakage of the wire bond can be prevented, preventing lowering of reliability in electric connection of the connection parts.

As described above, with the use of the lead frame and the semiconductor device using it according to the present invention, even if peeling off is caused between the lead frame and the sealing resin material, development of the peeling off is suppressed to prevent lowering of reliability in electric connection of the connection parts. Therefore, the present invention is useful for a lead frame for holding a semiconductor chip which requires the lead frame to have high heat radiation, such as a high breakdown voltage element or the like and a semiconductor device using it.

What is claimed is:

1. A lead frame comprising:
a die pad for holding a semiconductor chip;
a radiator plate extending outward from one side face of the die pad and another side face thereof opposite the one side;
a plurality of inner leads arranged opposite respective sides of the die pad other than the sides from which the radiator plate extends so as to interpose the die pad; and
a plurality of outer leads formed outside the plurality of inner leads and connected to the inner leads,
wherein at least one of the plurality of inner leads serves as a ground lead connected to the die pad, and
in the radiator plate, an island bonding area of which potential is equal to that of the die pad is formed, a first slit is formed around three sides of the island bonding area, and the other side is connected to the radiator plate through a joint part.

2. The lead frame of claim 1,
wherein the island bonding area is formed at a central part in a widthwise direction of the radiator plate which is a direction perpendicular to a direction that the radiator plate extends.

3. The lead frame of claim 1,
wherein a trench extending in a direction perpendicular to a direction that the inner leads extend is formed in a surface portion of each of the inner leads including the ground lead, and
the ground lead includes at least two bent portions bent in an in-plane direction of the ground lead.

4. The lead frame of claim 1,
wherein the island bonding area is in a quadrangular shape, a circular shape, an elliptical shape, a U-shape, or a V-shape in plan.

5. The lead frame of claim 1,
wherein the joint part has a width smaller than the island bonding area.

6. The lead frame of claim 1
wherein the first slit includes notches extending toward the inner leads on the respective sides of a part of the joint part which is connected to the radiator plate.

7. The lead frame of claim 1,
wherein the joint part is formed on an opposite side of the island boding area from the die pad.

8. The lead frame of claim 1,
wherein a trench extending in a direction perpendicular to a direction that the joint part extends is formed in a surface portion of the joint part.

9. The lead frame of claim 1,
wherein a second slit is formed in a region of the radiator plate on an opposite side of the island bonding area from the die pad, the region being sealed by a sealing resin material.

10. The lead frame of claim 1,
wherein the joint part is formed on a die pad side of the island bonding area.

11. The lead frame of claim 10,
wherein a third slit is formed between the die pad and the first slit of the radiator plate.

12. The lead frame of claim 1,
wherein a fourth slit is formed in a region of the radiator plate on an opposite side of the die pad from the island bonding area.

13. The lead frame of claim 1,
wherein a part of the ground lead which is connected to the die pad has a width smaller than the other inner leads.

14. The lead frame of claim 1,
wherein at least one out of the plurality of outer leads which is adjacent to an outer lead connected to the ground lead is not connected to any of the inner leads.

15. A semiconductor device using the lead frame of claim 1, comprising:
a semiconductor chip held on the die pad and having electrode pads and a ground electrode pad; and
a sealing part made of a sealing resin material for sealing the die pad including the semiconductor chip, each of the inner leads, and a part of the radiator plate which includes the island bonding area,
wherein in the semiconductor chip, the electrode pads are connected to the inner leads electrically by means of a metal thin line, and the ground electrode pad is connected to the island bonding area or a bonding area of the ground lead electrically by means of a metal thin line,
the island bonding area is covered at peripheral sides thereof, except a side connected to the joint part, with the sealing resin material, and
the other part of the radiator plate and each of the outer leads are bent in gull wind forms.

16. The semiconductor device of claim 15,
wherein the semiconductor chip is a high breakdown voltage element.

17. A lead frame comprising:
a die pad for holding a semiconductor chip;
a radiator plate extending outward from one side face of the die pad and another side face thereof opposite the one side;
a plurality of inner leads arranged opposite respective sides of the die pad other than the sides from which the radiator plate extends so as to interpose the die pad; and
a plurality of outer leads formed outside the plurality of inner leads and connected to the inner leads,
wherein at least one of the plurality of inner leads serves as a ground lead connected to the die pad,
a trench extending in a direction perpendicular to a direction that the inner leads extend is formed in a surface portion of each of the inner leads including the ground lead, and
the ground lead includes at least two bent portions bent in an in-plane direction of the ground lead.

18. The lead frame of claim 17,
wherein a part of the ground lead which is connected to the die pad has a width smaller than the other inner leads.

19. The lead frame of claim 17,
wherein at least one out of the plurality of outer leads which is adjacent to an outer lead connected to the ground lead is not connected to any of the inner leads.

20. A semiconductor device using the lead frame of claim 17, comprising:
a semiconductor chip held on the die pad and having electrode pads and a ground electrode pad; and
a sealing part made of a sealing resin material for sealing the die pad including the semiconductor chip, each of the inner leads, and a part of the radiator plate which includes the island bonding area,
wherein in the semiconductor chip, the electrode pads are connected to the inner leads electrically by means of a metal thin line, and the ground electrode pad is connected to the island bonding area or a bonding area of the ground lead electrically by means of a metal thin line,
the island bonding area is covered at peripheral sides thereof, except a side connected to the joint part, with the sealing resin material, and
the other part of the radiator plate and each of the outer leads are bent in gull wind forms.

21. The semiconductor device of claim 20,
wherein the semiconductor chip is a high breakdown voltage element.
